(19) United States
(12) Patent Application Publication
(10) Pub. No.: US 2003/0052000 A1
(43) Pub. Date: Mar. 20, 2003

(54) Fine grain size material, sputtering target, methods of forming, and micro-arc reduction method

(76) Inventors: Vladimir Segal, Veradale, WA (US); Michael E. Thomas, Milpitas, CA (US); Jianxing Li, Albuquerque, NM (US); Stephane Ferrasse, Veradale, WA (US); Frank Alford, Veradale, WA (US); Tim Scott, Post Falls, ID (US); Stephen Turner, Moon Township, PA (US)

Correspondence Address: WELLS ST. JOHN ROBERTS GREGORY & MATKIN P.S., 601 W. FIRST AVENUE, SUITE 1300, SPOKANE, WA, 99201-3828, US

(21) Appl. No.: 10/225,272

(22) Filed: Aug. 20, 2002

Related U.S. Application Data
(63) Continuation-in-part of application No. 09/586,326, filed on Jun. 2, 2000, now abandoned.
(63) Continuation-in-part of application No. 09/098,761, filed on Jun. 17, 1998.
(60) Provisional application No. 60/052,218, filed on Jul. 11, 1997.

(51) Int. Cl. C23C 14/34

(52) U.S. Cl. 204/298.13; 420/591; 428/544

(57) ABSTRACT

A material may include grains of sizes such that at least 99% of a measured area contains grains that exhibit grain areas less than 10 times an area of a mean grain size of the measured area. As examples, at least 99% of the measured area may contain grains with grain areas less than 8, 6, or 3 times the area of the mean grain size. The grains may also have a mean grain size of less than 3 times a minimum statically recrystallized grain size, for example, a mean grain size of less than about 50 microns, 10 microns, or 1 micron. The material may be comprised by a sputtering target and a thin film may be deposited on a substrate from such a sputtering target. A micro-arc reduction method may include sputtering a film from a sputtering target comprising grains of sizes as described. A sputtering target forming method may include deforming a sputtering material. After the deforming, the sputtering material may be shaped into at least a portion of a sputtering target. The sputtering target may include grains of sizes as described. Also, the deforming may induce a strain level corresponding to ε of at least about 4. Further, the deforming may include equal channel angular extrusion.

### RELATED PATENT DATA

The present application is a continuation-in-part application of U.S. patent application Ser. No. 09/586,326 filed Jun. 2, 2000 entitled “Fine Grain Size Material, Sputtering Target, Methods of Forming, and Micro-Arc Reduction Method” that is hereby incorporated by reference in its entirety. The present application is also a continuation-in-part application of U.S. patent application Ser. No. 09/098,761 filed Jun. 17, 1998 entitled “Metal Article with Fine Uniform Structures and Textures and Process of Making Same” that is hereby incorporated by reference in its entirety and that claims priority from U.S. Provisional Application No. 60/052,218 filed Jul. 11, 1997.

### TECHNICAL FIELD

The invention pertains to fine grain materials and sputtering targets as well as methods of forming them and micro-arc reduction methods.

### BACKGROUND OF THE INVENTION

Sputtering (also referred to as physical vapor deposition (PVD)) is a technology by which thin metallic and/or ceramic layers can be deposited onto a substrate. Sputtered materials come from a target, which serves generally as a cathode in a standard radio-frequency (RF) and/or direct current (DC) sputtering apparatus. For example, PVD is widely used in the semiconductor industry to produce integrated circuits.

Sputtering targets can be formed of numerous metals and alloys. Some suitable materials are Al, Ti, Cu, Ta, Ni, Mo, Au, Ag, and Pt among others, as well as alloys thereof, including alloys with these and or other elements. To provide high resolution of sputter deposited thin films, as well as to provide uniform and step coverages, effective sputtering rate and other requirements, targets should have homogenous composition, fine and uniform structure, controllable texture and be free from precipitates, particles and other inclusions. Also, they should have high strength and simple options for recycling. Therefore, significant improvements are desired in the metallurgy of targets.

Some targets may be quite large in size, a typical target used in fabrication of liquid crystal displays (LCD) being 860×910×19 mm³, and are expected to become bigger in the future. Those dimensions can pose additional challenges to the development of tooling and processing for fabrication of suitable targets.

Various works demonstrate that three fundamental factors of a target can influence sputtering performance. The first factor is the grain size of the material, i.e. the smallest constitutive part of a polycrystalline metal possessing a continuous crystal lattice. Grain size ranges are usually from several millimeters to a few tenths of microns depending on metal nature, composition, and processing history. It is believed that finer and more homogeneous grain sizes improve thin film uniformity, sputtering yield and deposition rate, while reducing micro-arcing.

The second factor is target texture. The continuous crystal lattice of each grain is oriented in a specific way relative to the plane of target surface. The sum of all the particular grain orientations defines the overall target orientation. When no particular target orientation dominates, the texture is considered to be a random structure. Like grain size, crystallographic texture strongly depends on the preliminary thermomechanical treatment, as well as on the nature and composition of a given metal. Crystallographic textures can influence thin film uniformity and sputtering rate.

The third factor is the size and distribution of structural components, such as second phase precipitates and particles, and casting defects (such as, for example, voids or cavities). These structural components are usually not desired and can be sources for arcing as well as contamination of thin films.

In order to improve the manufacture of targets it would be desirable to reduce micro-arcing and reduce the generation of particles that originate from the target during sputtering.

### SUMMARY OF THE INVENTION

According to one aspect of the invention, a material may include grains of sizes such that at least 99% of a measured area contains grains that exhibit grain areas less than 10 times an area of a mean grain size of the measured area. As examples, at least 99% of the measured area may contain grains with grain areas less than 8, 6, or 3 times the area of the mean grain size. The grains may also have a mean grain size of less than 3 times a minimum statically recrystallized grain size. Mean grain size may also be less than the minimum statically recrystallized grain size. As examples, the grains may have a mean grain size of less than about 50 microns, about 1 to about 10 microns, or about 0.1 to about 1 micron. The measured area may include at least about a representative area. The material may comprise one or more of Be, B, C, Mg, Al, Si, Ca, Sc, Ti, V, Cr, Mn, Fe, Co, Ni, Cu, Zn, Ga, Ge, Se, Sr, Y, Zr, Nb, Mo, Ru, Pd, Ag, In, Sn, Sb, Ba, La, Hf, Ta, W, Ir, Pt, Au, Bi, Ce, Nd, Sm, Eu, Gd, Tb, or Dy.

A sputtering target may comprise the material described above. Also, a thin film may be deposited on a substrate from such a sputtering target.

A micro-arc reduction method may include sputtering a film from a sputtering target comprising grains of sizes such that at least 99% of a measured area contains grains that exhibit grain areas less than 10 times an area of a mean grain size of the measured area. The sputtering target grains may have a mean grain size of less than 3 times a minimum statically recrystallized grain size.

A sputtering target forming method may include deforming a sputtering material. After the deforming, the sputtering material may be shaped into at least a portion of a sputtering target. The sputtering target may include grains of sizes such that at least 99% of a measured area contains grains that exhibit areas less than 10 times an area of a mean grain size of the measured area. As an example, the deforming may include equal channel angular extrusion. Also, the deforming may induce an accumulated strain level corresponding to ε of at least about 4.

### BRIEF DESCRIPTION OF THE DRAWINGS

Preferred embodiments of the invention are described below with reference to the following accompanying drawings.

FIGS. 1-4 are schematic diagrams showing processing steps of billet preparation for ECAE.

FIG. 5A is a schematic diagram showing non-uniform microstructure.

FIG. 5B is a schematic cross-sectional diagram of a sputtering target having the microstructure shown in FIG. 5A during a sputtering process.

FIG. 5C shows an optical micrograph of nickel-vanadium alloy illustrating non-uniformity in grain size distribution.

FIG. 6 shows an optical micrograph of high purity tantalum having a duplex, non-uniform microstructure.

FIG. 7 shows an optical micrograph of high purity nickel having a duplex, non-uniform microstructure.

FIG. 8A is a graph showing a grain area distribution for conventionally processed titanium.

FIG. 8B is a graph showing a grain area distribution for titanium processed by a high strain technique.

FIG. 9A is a graph showing a grain area distribution for conventionally processed copper.

FIG. 9B is a graph showing a grain area distribution for copper processed by a high strain technique.

FIG. 10A shows an optical micrograph of a conventional microstructure for high purity copper.

FIG. 10B shows an optical micrograph of a microstructure produced by a high strain processing technique for high purity copper.

FIGS. 11, 11A and 11B are schematic diagrams of an apparatus for ECAE of billets for targets.

FIG. 12 shows a flow chart diagram of a method of the present invention.

FIG. 13 shows a flow chart diagram of a method of evaluating a grain area distribution.

### DETAILED DESCRIPTION OF THE PREFERRED EMBODIMENTS

As semiconductor feature sizes have decreased rapidly over the last decade, particles originating from a sputtering target may have become more significant. Particles previously too small to cause problems may be increasingly likely to cause device failure or to significantly effect wafer yields. Investigation has indicated an increasing importance in eliminating regions of a sputtering target prone to micro-arcing. Such investigation also indicates that sputter target microstructures that are more uniform and more fine grain sizes may assist in reducing micro-arcing. In particular, new methods of characterizing sputtering targets may be needed. Conventionally, sputtering targets are certified with a mean grain size number using measurements taken from one location or averaged from many locations on a target. Even targets that exhibit a fine mean grain size may possess excessively large grains within a distribution of grain sizes that may significantly effect sputtering performance. Accordingly, sputtering targets having a narrow distribution of grain sizes may be beneficial. Such targets may additionally have a fine mean grain size.

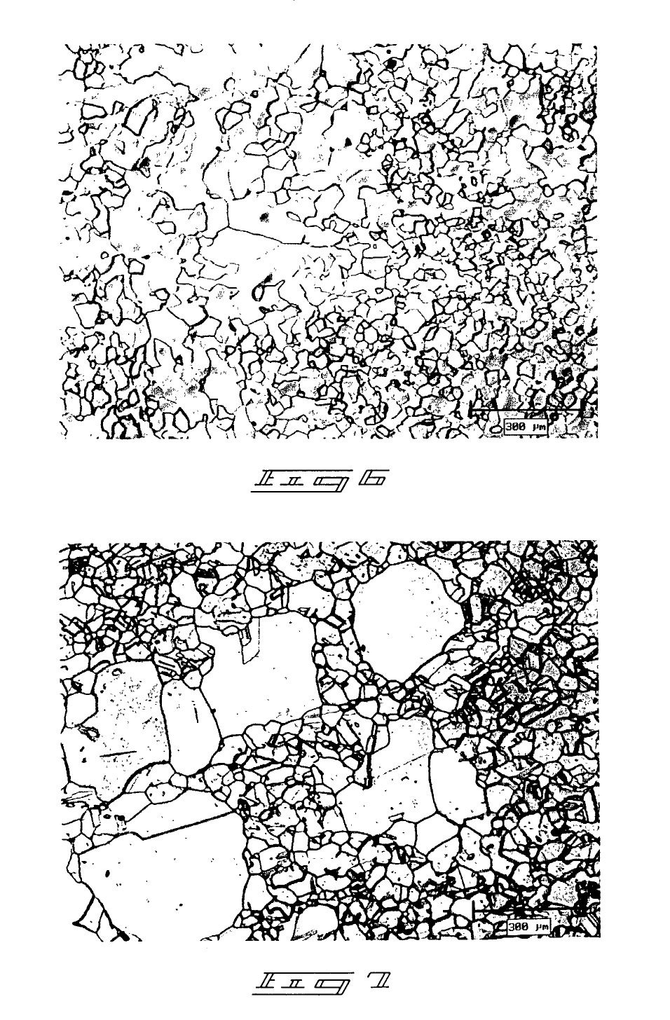

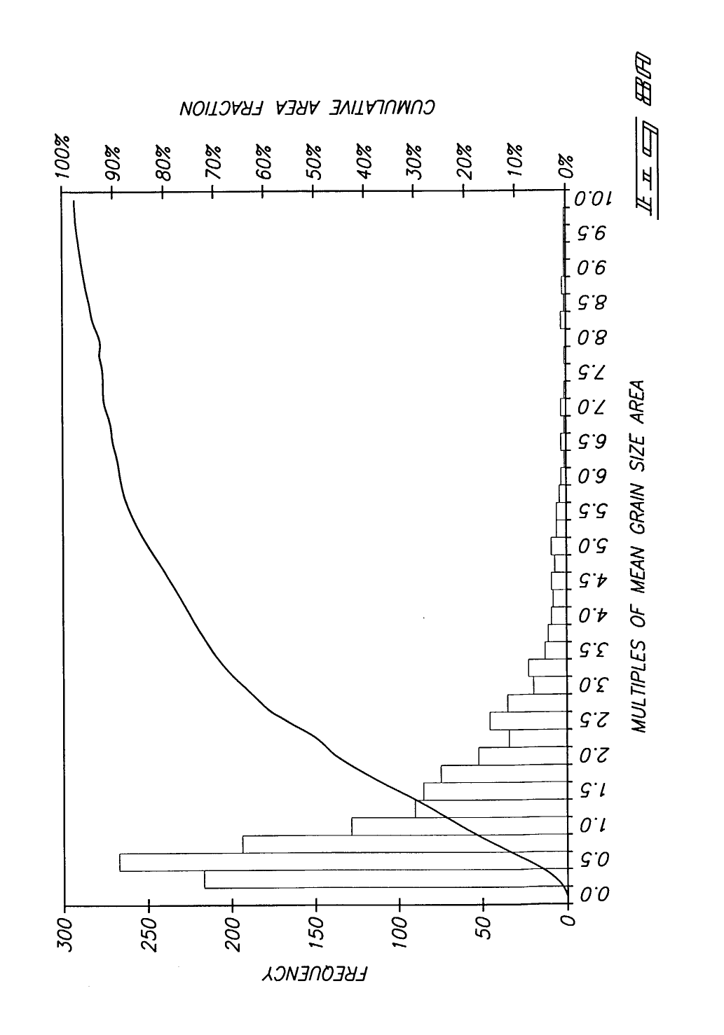

Turning to FIG. 5A, an exemplary non-uniform microstructure is presented such as might be produced by conventional thermo-mechanical processes. Note a wide distribution of grain sizes is presented. FIG. 5B displays such a material in a sputtering target 20 undergoing a sputter deposition process. As energy is applied to sputtering target 20, micro-arcing 26 occurs in association with large grains 24 to generate particles 22. The more finely grained region 28 away from larger grains 24 tends to produce a smooth sputter surface without generation of particles 22. FIG. 5C shows a nickel-vanadium material formed using conventional processes and illustrating the non-uniformity in grain sizes that may occur.

Micro-arcing and generation of particles from a sputtering target may be reduced by eliminating large grains and clusters of large grains within a target. The level of elimination of large grains may be evaluated both within a localized microstructure as well as from region to region of a target. Accordingly, it may not be sufficient merely to characterize a sputtering target with a mean grain size derived from a distribution and/or multiple locations on a target without additional characterization parameters.

Some materials, such as copper, nickel, nickel-vanadium, tantalum, and others, suffer from non-uniformity of grain sizes in the form of duplex grain structure. Two types of duplex grain structure can exist. A first type exhibits agglomerations of large grains within a matrix of small grains, or vice versa. A second type exhibits a more continuous dispersion with a small amount of grains scattered throughout a target matrix that are outside a desired normal distribution of grain sizes. Both types of structures may be detrimental to a sputtering process when large grains in clusters or in isolated spots increase the propensity for micro-arcing. Some metals, such as titanium, aluminum, aluminum alloys, and others, are not typically thought to suffer from duplex grain size distributions, however, grain size distributions produced in such materials by conventional thermo-mechanical processing may be too wide for the demands of sputtering targets as described above.

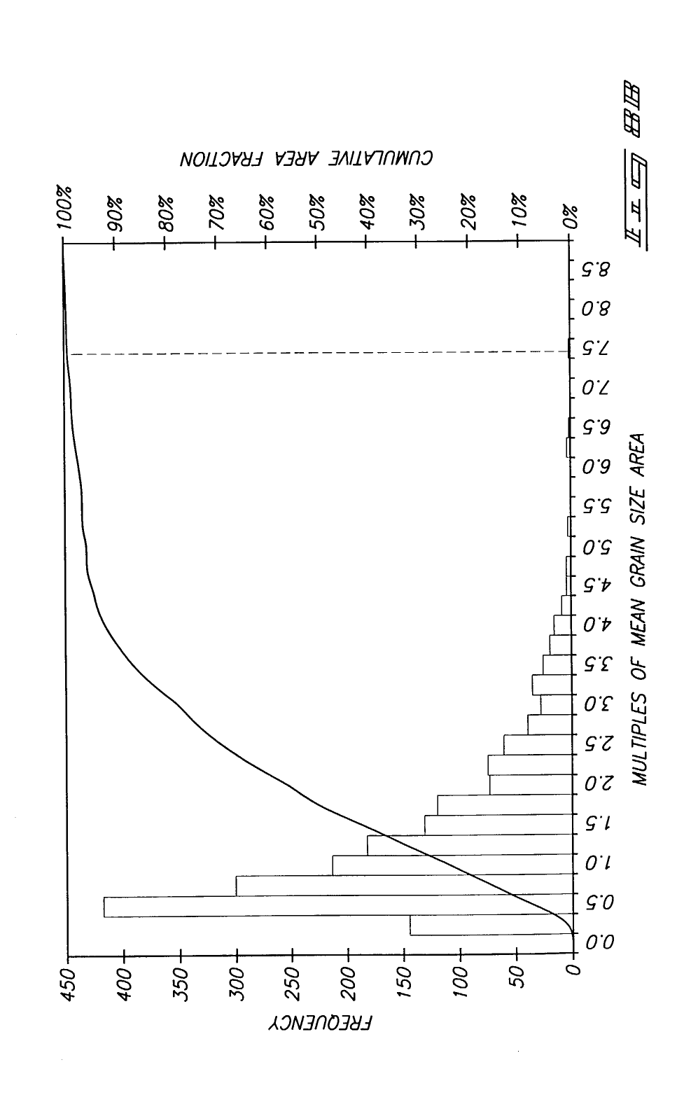

As an example, FIGS. 6 and 7 illustrate duplex grain structures. FIG. 6 shows duplex, non-uniform microstructures of high purity tantalum as may be produced by conventional thermo-mechanical processing techniques. FIG. 7 shows a similar duplex, non-uniform microstructure for high purity nickel produced by conventional thermo-mechanical processing techniques as well.

According to one aspect of the invention, a material may include grains of sizes such that at least 99% of a measured area contains grains that exhibit grain areas less than 10 times an area of a mean grain size of the measured area. As examples, at least 99% of the measured area may contain grains with grain areas less than 8, 6, or 3 times the area of the mean grain size. Grain area may be calculated by any current or future method known to those skilled in the art. One suitable method is to measure grain diameter as viewed from a micrograph and to approximate grain area to a circle of the same diameter. For the mean grain size area, a mean grain size may be determined by conventional methods and then a mean area may be approximated as a circle of the same diameter. Other methods for determining mean grain size area may also be suitable.

A distribution of grain sizes as described above reduces the occurrence of micro-arcing and the generation of particles from a sputtering target by reducing the number and size of excessively large grains within a microscopic region. The grains may also have a mean grain size of less than 3 times a minimum statically recrystallized grain size. Mean grain size may also be less than the minimum statically recrystallized grain size. As examples, the grains may have a mean grain size of less than about 50 microns, about 1 to about 10 microns, or about 0.1 to about 1 micron. For many, but not all, materials conventionally used in sputter deposition, the minimum statically recrystallized grain size may fall within the range about 1 to about 10 microns. Also, for such materials, the range of dynamically recrystallized grain sizes may fall within about 0.1 to about 1 micron.

The measured area may include at least about a statistically representative area. Statistically representative area may be calculated by any current or future method known to those skilled in the art. The objective of selecting at least about a representative area is to include a large enough number of grains in measuring mean grain size and grain size distribution that the data accurately reflects the overall microstructure of the material. Less than a representative area might skew data such that a more narrow or wide distribution of grain sizes is calculated than would result from evaluating the entirety of measurable surfaces of a specimen. For example, the measured area may include at least about 1000 coherent (joined together) grains of the material. Evaluating all of the surfaces of a specimen that are conducive to the measurements indicated (i.e., measurable) may be possible. Even so, evaluating representative areas is more efficient and, thus, desirable. One suitable method is described in association with ASTM Test Method E112, Standard Test Methods for Determining Average Grain Size. Also, rules of thumb or other methods may be known in the art for selecting a representative area. Such other methods may include one or more of the various test methods referenced by ASTM E112. In keeping with the various aspects of the invention described herein, FIG. 13 shows one method for evaluating a grain area distribution.

Materials that may possess grains having the properties described above may include one or more of Be, B, C, Mg, Al, Si, Ca, Sc, Ti, V, Cr, Mn, Fe, Co, Ni, Cu, Zn, Ga, Ge, Se, Sr, Y, Zr, Nb, Mo, Ru, Pd, Ag, In, Sn, Sb, Ba, La, Hf, Ta, W, Ir, Pt, Au, Bi, Ce, Nd, Sm, Eu, Gd, Tb, or Dy. The material may also consist essentially of one of the listed elements. The material may include at least about 90 atomic % of a matrix element, such as Al, Ti, Cr, Co, Ni, Cu, Zr, Ru, Ag, In, Sn, Hf, Ta, Ir, Pt, or Au, and from about 0.01 to about 10 atomic % of one or more of an alloying element. The material may also include at least about 95 atomic % of a matrix element and from about 0.1 to about 5 atomic % of one or more of an alloying element. Alloying elements may include one or more of the first listed elements above. Alloying elements may also include one or more of transition elements, such as Al, Si, Ti, Cu, Ga, Nb, Mo, Pd, Ag, In, Sn, Ta, W, or Au, and may instead include reactive elements, such as Mg, Ca, Sc, Sr, Y, Zr, Ba, La, Hf, Ce, or Nd.

In another aspect of the invention, a sputtering target may comprise the described material. In an additional aspect, a thin film may be deposited on a substrate from such a sputtering target. In yet another aspect of the invention, a material may consist of grains of sizes such that at least 99% of any measured surface area consists of grains that exhibit grain areas less than 10 times an area of a mean grain size of the measured surface area.

In keeping with the above-described advantages of desirable materials for sputtering targets, a micro-arc reduction method may include sputtering a film from a sputtering target comprising grains of sizes such that at least 99% of a measured area consists of grains that exhibit grain areas less than 10 times an area of a mean grain size of the measured area. The sputtering target grains may also have a mean grain size of less than 3 times a minimum statically recrystallized grain size.

As another aspect of the invention, a sputtering target may be formed by a method including deforming a sputtering material. After the deforming, the sputtering material may be shaped into at least a portion of a sputtering target. The sputtering target may comprise grains of sizes such that at least 99% of a measured area consists of grains that exhibit grain areas less than 10 times an area of a mean grain size of the measured area. The deforming may include a high strain processing technique or severe plastic deformation. Further, the deforming may induce an accumulated strain level corresponding to ε of at least about 4. The high strain processing technique or severe plastic deformation may include at least one of equal channel angular extrusion, high strain rate forging, or other methods. The manufacturing process may further include rapid quenching and rapid thermal annealing. One rapid quenching technique may include die casting with accompanying rapid cooling to achieve a small grain size and the desired microstructure.

The manufacturing process may also include a combination of thermo-mechanical processing and material alloying and/or doping. Although alloying and/or doping additions are typically not used to refine microstructures, carefully chosen additions to pure materials can stabilize grain sizes and reduce discontinuous grain growth enabling fine uniform microstructures to be achieved without significantly affecting the properties of sputtered film. For example, doping of high purity aluminum with several different transition metals may be successfully used to produce a grain size distribution according to the present invention that may be otherwise difficult to obtain in pure aluminum.

Powder metallurgy is another possible mechanism for producing the desired microstructure in a sputter target. Targets with the desired microstructure can be made using carefully screened material powders, preferable nano-powders, followed by compaction and sintering steps.

High strain techniques, such as those listed and others, are suitable for forming a microstructure according to the various aspects of the invention described above. Traditional thermo-mechanical processing techniques, such as forging, rolling, and annealing may not deliver uniform enough deformation to eliminate large grains in a material without the help of alloying additions and/or dopants. Such traditional processes typically produce a significant number of grains with an area of more than 10 times or much more than 10 times the area of a mean grain size. By contrast, some of the listed methods of the present aspect of the invention impart a high degree of strain in a very uniform manner and/or ultra high strain rates in rapid thermal treatments. The desired microstructural control may also be achieved in materials alloyed with additions that control grain stability and growth that are processed with a high degree of strain.

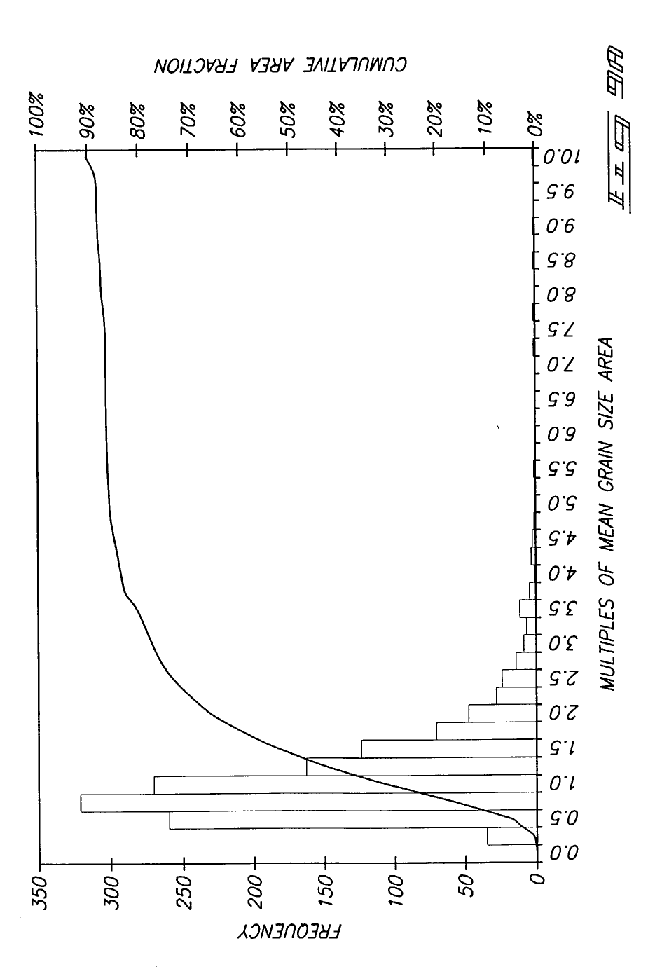

The graph of FIG. 8A illustrates a grain size distribution as it occurred in titanium processed according to conventional thermo-mechanical techniques. Such a distribution includes large grains that may increase a propensity for micro-arcing during sputter deposition of such a material when incorporated into a sputtering target. As indicated in FIG. 8A, at 99% of a measured area as indicated by the Cumulative Area Fraction the grains within such measured area include grains having a grain area of 12.2 times the area that corresponds to a mean grain size, in other words, the mean grain size area. For the data illustrated in the graph of FIG. 8A, the total area measured was 82,177 square microns. Within the measured area, mean grain size was measured as 7.7 microns which calculates to a mean grain size area of 46.6 square microns. FIG. 8A may be contrasted with FIG. 8B illustrating a grain size distribution according to the various aspects of the present invention for titanium processed by a high strain technique. The material analyzed to produce the graph of FIG. 8B exhibited a mean grain size of 5.9 microns to yield a mean grain size area of 27.3 square microns within a measured area of 62,192 square microns. As shown in FIG. 8B, 99% of the measured area consisted of grains exhibiting grain areas less than about 7.4 times the mean grain size area.

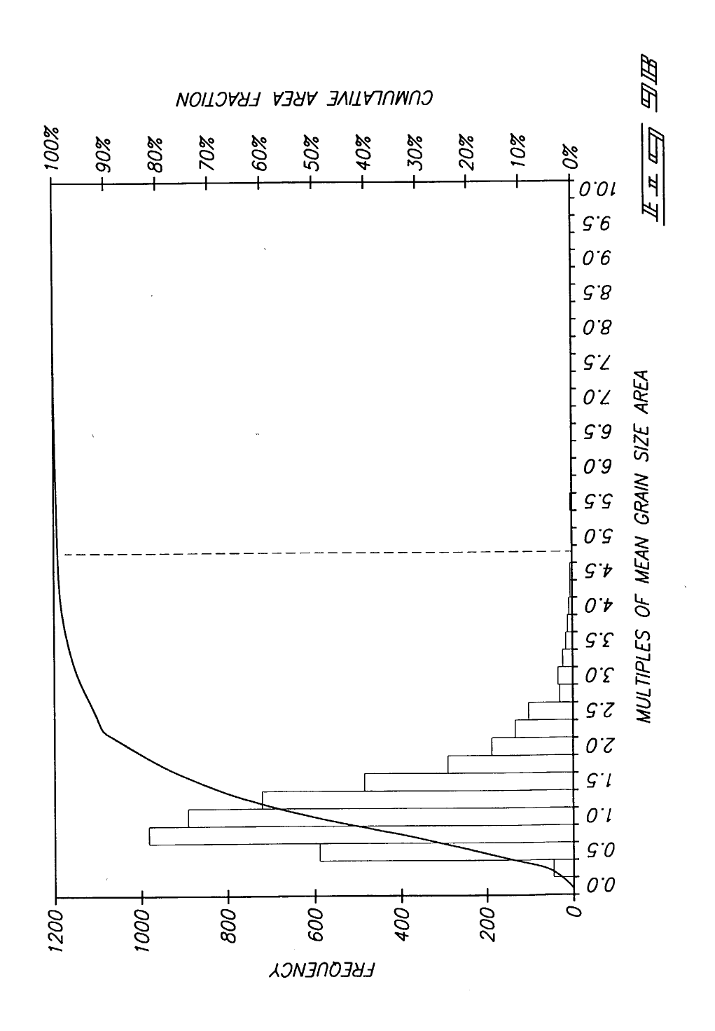

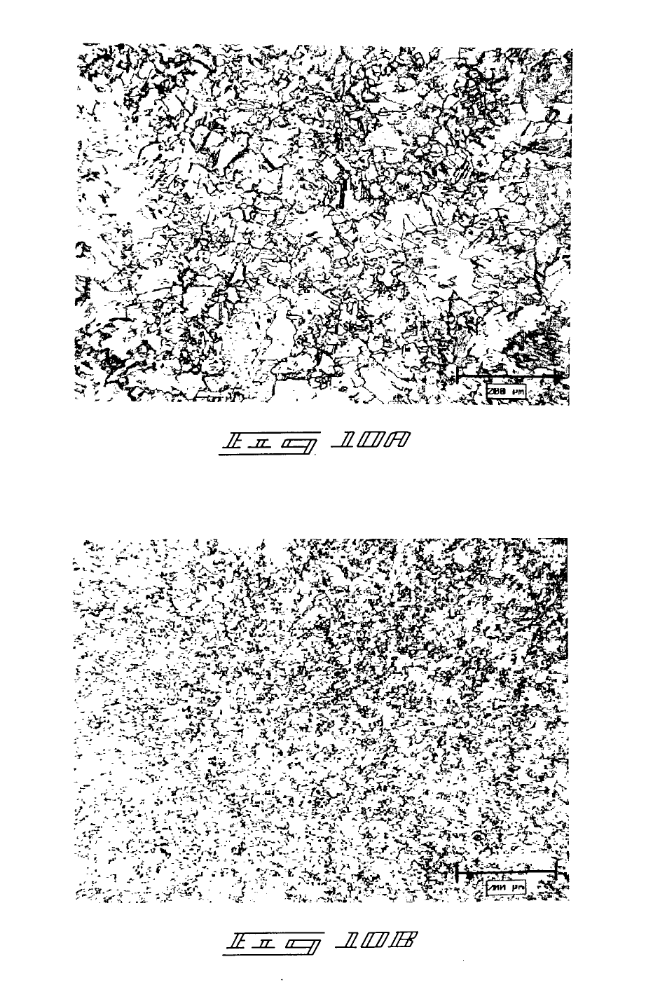

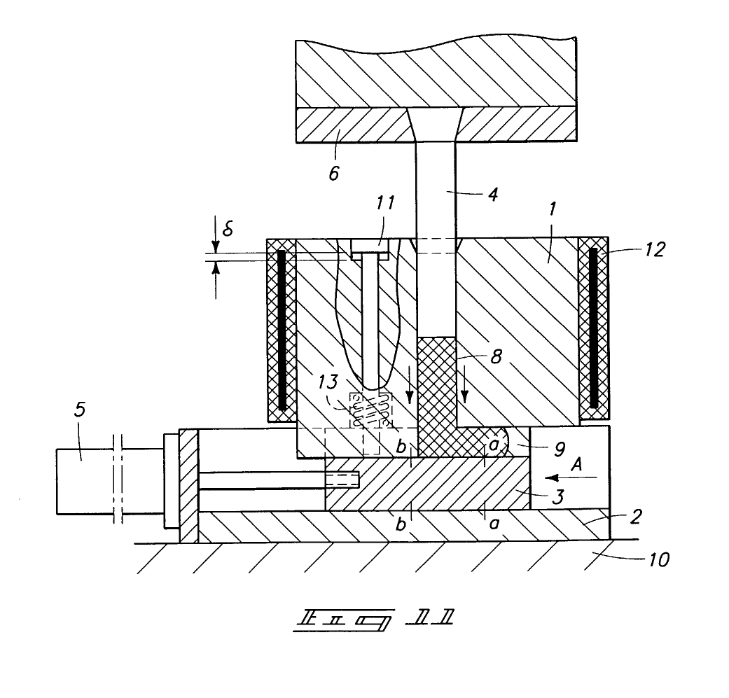

FIGS. 9A and 9B illustrate data for copper material analogous, respectively, to the data shown in FIGS. 8A and 8B. In FIG. 9A, mean grain size was 20.7 microns to yield a mean grain size area of 336.5 square microns within a measured area of 692,481 square microns. At 99% of the measured area the grains had grain areas of less than 37 times the mean grain size area. Such evidences the existence of larger grains that may increase the propensity for micro-arcing. The grain size distribution of FIG. 9B is shown to be more narrow in keeping with the various aspects of the present invention. Specifically, the copper material evaluated for FIG. 9B exhibited a mean grain size of 19.2 microns to yield a mean grain size area of 289.5 square microns within a measured area of 1,435,689 square microns. At 99% of the measured area the grains had grain areas of less than 4.75 times a mean grain size area of the measured area. An example of a high purity copper material exhibiting the type of grain area distribution of FIG. 9A is shown in FIG. 10A. By comparison, the type of high purity copper material exhibiting the grain size distribution of FIG. 9B is shown in FIG. 10B. The differences in distribution of grain sizes in FIG. 10B in comparison to FIG. 10A is readily apparent.

A special deformation technique known as equal channel angular extrusion (ECAE) is used with advantage for the manufacture sputtering targets. The technique was invented by V. M. Segal, and is described in U.S. Pat. Nos. 5,400,633; 5,513,512; 5,600,989; and 5,590,389. Another deformation technique is described in pending U.S. patent application Ser. No. 09/098,761, filed Jun. 17, 1998. The disclosure of the aforementioned patents and patent application is expressly incorporated herein by reference.

The general principle of ECAE utilizes two intersecting channels of approximately identical cross-section through which a billet is extruded to induce deformations within the billet. The intersecting channels are preferably exactly identical in cross-section to the extent that “exactly identical” can be measured and fabricated into an ECAE apparatus. However, the term “approximately identical” is utilized to indicate that the cross-sections may be close to exactly identical, instead of exactly identical, due to, for example, limitations in fabrication technology utilized to form the intersecting channels.

An ECAE apparatus induces plastic deformation in a material passed through the apparatus. Plastic deformation is realized by simple shear, layer after layer, in a thin zone at a crossing plane of the intersecting channels of the apparatus. A remarkable feature of ECAE is that the billet shape and dimensions remain substantially unchanged during processing (with term “substantially unchanged” indicating that the dimensions remain unchanged to the extent that the intersecting channels have exactly identical cross-sections, and further indicating that the channels may not have exactly identical cross-sections).

The ECAE technique can have numerous advantages. Such advantages can include: strictly uniform and homogeneous straining; high deformation per pass (ε=1.17, with ε having a conventional meaning of corresponding to the natural log of a reduction ratio); high accumulated strains due to multiple passes (at N=4 passes, ε=4.64); different deformation routes, i.e. change of billet orientation at each pass allowing for the creation of various textures and microstructures; and low load and pressure.

ECAE can enable a decrease in the grain size of high purity alloys by at least a factor of three compared to conventional practices.

ECAE can also offer additional advantages over conventional practices in terms of texture control.

A preferred target possesses: a substantially homogeneous composition throughout; a substantial absence of pores voids, inclusions and any other casting defects; a predominate and controlled grain size of less than about 50 micrometers; and a substantially uniform structure and controlled texture throughout. Very fine and uniform precipitates with average grain diameters of less than 0.5 micrometers can also be present in a preferred target microstructure.

Sputtering targets of the present invention can be formed from a cast ingot made of any of the metals listed above. Such ingot can be heat treated and processed by one or more of homogenizing, hot forging, aging, and extrusion through a die possessing two contiguous channels of equal cross section intersecting each other at a certain angle. The ingot material can also be subjected to annealing and/or processing with conventional target-forming processes such as rolling, cross-rolling or forging, and fabricated into a sputtering target. The extrusion step can be repeated several times via different deformation routes before final annealing, conventional processing and fabrication steps to produce very fine and uniform grains sizes within a processed material, as well as to control texture strength and orientation within the material.

Processes of the present invention can be applied to large targets comprised of two or more segments.

A sputtering target of the present invention can have the characteristics of:

substantially homogenous material composition at any location;

substantial absence of pores, voids, inclusions and other casting defects;

substantial absence of precipitates;

grain size less than about 1 μm;

fine stable structure for sputtering applications;

substantially uniform structure and texture at any location;

high strength targets without a backing plate;

controllable textures from strong to middle, weak and close to random;

controllable combination of grain size and texture;

large monolithic target size;

prolonged sputtering target life; and

optimal gradient of structures through target thickness.

Targets possessing these characteristics are producible by the processes described herein.

Because of high purity, cast ingot metallurgy is useful in most cases for billet fabrication in target production. However, casting results in a very course dendritic structure with strong non-uniformity in the distribution of constitutive elements and additions across the ingot and large crystallites. Moreover, high temperature and long-time homogenizing cannot be applied in current processing methods because of the further increase of grains. One embodiment of the invention solves this problem by using homogenizing time and temperature sufficient for redistribution of macrosegregations and microsegregations followed by equal channel angular extrusion (ECAE) with a sufficient number of passes, preferably from 4 to 6, for grain refinement.

Another embodiment eliminates other casting defects such as voids, porosity, cavities, gases, and inclusions which cannot be optimally removed by homogenizing and employs a hot forging operation. In currently known methods hot forging has a restricted application because reductions are limited and are typically used at low temperature working for grain refinement. Other processes do not solve that problem when slab ingots of the same thickness as the billet for ECAE are used. In the present invention, the as-cast ingot has a large length-to-diameter ratio, preferably up to 2. During hot forging, the ingot thickness changes to the thickness of the billet for ECAE. That provides large reductions which are sufficient for full healing and elimination of cast defects.

Still another embodiment of the invention is directed to precipitate and particle-free targets. With currently known methods precipitate-free material may be prepared by solutionizing at the last processing step. However, in this case heating to solutionizing temperatures produces very large grains. The present invention provides a method for fabricating precipitate-free and ultra-fine grained targets. According to this embodiment of the invention, solutionizing is performed at a temperature and time necessary to dissolve all precipitates and particle bearing phases and is followed by quenching immediately before ECAE. Subsequent ECAE and annealing are performed at temperatures below aging temperatures for corresponding material conditions.

A further embodiment of the invention is a special sequence of homogenizing, forging and solutionizing operations. As-cast ingots are heated and soaked at the temperature and for the length of time necessary for homogenizing, then cooled to the starting forging temperature, then forged to the final thickness at the final forging temperature (which is above the solutionizing temperature) and quenched from this temperature. By this embodiment all processing steps are performed with one heating. This embodiment also includes another combination of processing steps without homogenizing: forging at a temperature of about the solutionizing temperature and quenching immediately after forging.

It is also possible in accordance with the invention to conduct aging after solutionizing at the temperature and for the length of time necessary to produce fine precipitates with an average diameter of less than 0.5 μm. These precipitates will promote the development of fine and uniform grains during following steps of ECAE.

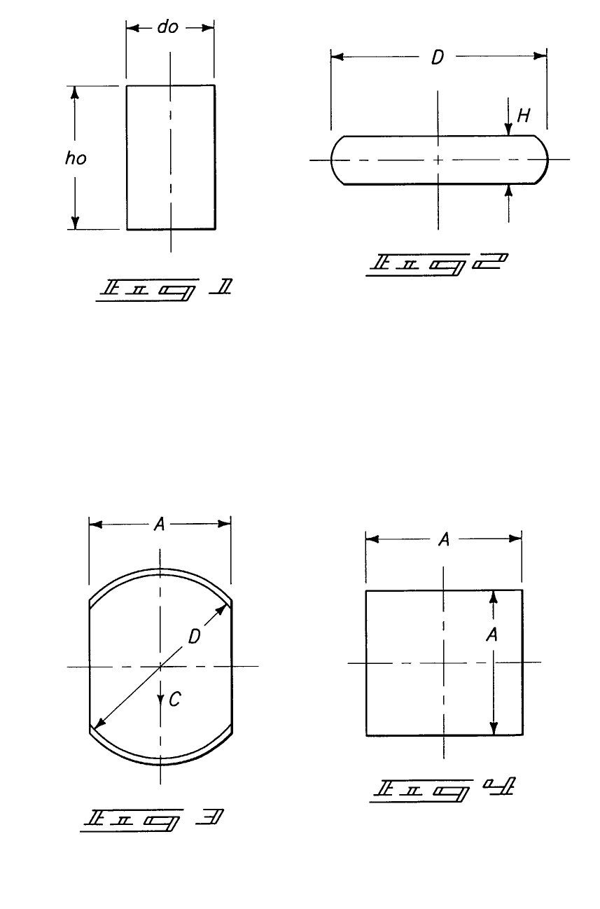

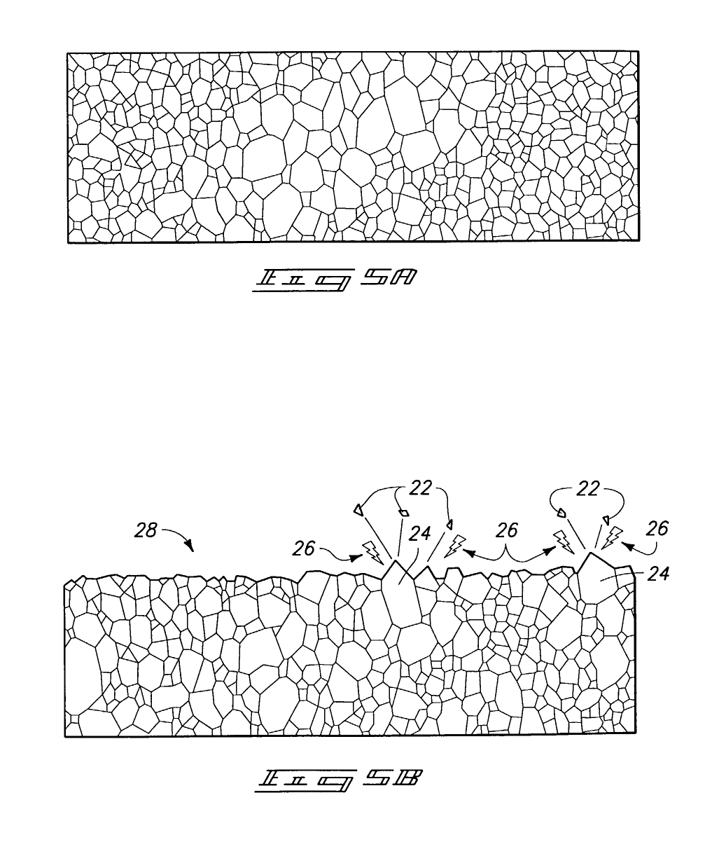

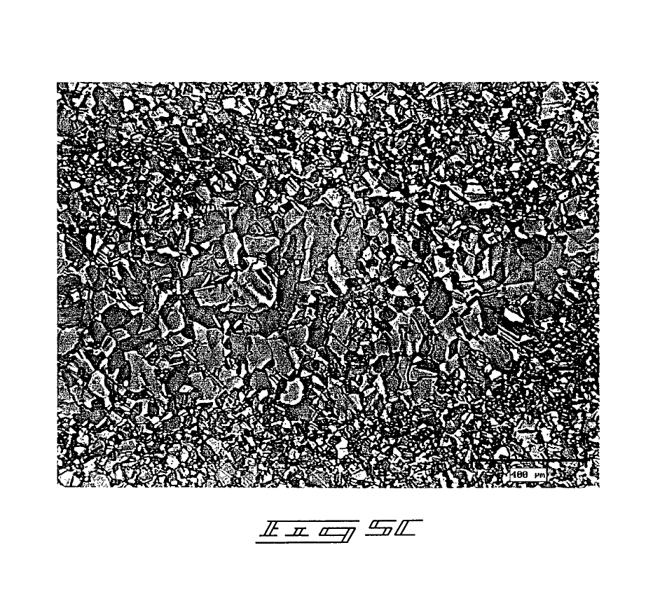

An additional embodiment of the invention is a billet for ECAE after forging. An as-cast cylindrical ingot of diameter d₀ and length h₀ (FIG. 1) is forged into a disk of diameter D and thickness H (FIG. 2). The thickness H corresponds to the thickness of the billet for ECAE. Then two segments are removed from two opposite sides of the forged billet such as by machining or sawing (FIG. 3), to provide a dimension A corresponding to a square billet for ECAE (FIG. 4). ECAE is performed in direction “C” shown on FIG. 3. After the first pass the billet has a near-square shape if the dimensions of the ECAE billet (A×A×H), the dimensions of the forged disk (D×H) and the dimensions of the cast ingot (d₀×h₀) are related by the following formulae:

D=1.18A

d₀²h₀=1.39.A²H

The invention further contemplates the fabrication of targets with fine and uniform grain structure. ECAE is performed at a temperature below the temperature of static recrystallization with the number of passes and processing route adjusted to provide dynamic recrystallization during ECAE. Processing temperature and speed are, correspondingly, sufficiently high and sufficiently low to provide macro- and micro-uniform plastic flow.

A method for fabricating fine and stable grain structures for sputtering applications and to provide high strength targets is also provided. The billet after ECAE with dynamically recrystallized sub-micron structure is additionally annealed at the temperature which is equal to the temperature of the target surface during steady sputtering. Therefore, the temperature of the target cannot exceed this sputtering temperature for structure to remain stable during target life. That structure is the finest presently possible stable structure and provides the best target performance. It also provides a high strength target. Thus, among other things, the invention provides the following significant advantages:

High strength monolithic targets may be fabricated from mild materials like pure aluminum, copper, gold, platinum, nickel, titanium and their alloys;

It is not necessary to use backing plates with additional and complicated operations such as diffusion bonding or soldering;

Fabrication of large targets is not a problem; and

Targets may easily be recycled after their sputtering life ends.

An additional embodiment comprises a two-step ECAE processing. At the first step ECAE is performed with a low number of passes, preferably from 1 to 3, in different directions. Then, the preliminary processed billet receives aging annealing at low enough temperatures but for sufficient time to produce very fine precipitates of average diameter less than about 0.1 μm. After intermediate annealing ECAE is repeated with the number of passes necessary to develop a dynamically recrystallized structure with the desired fine and equiaxed grains.

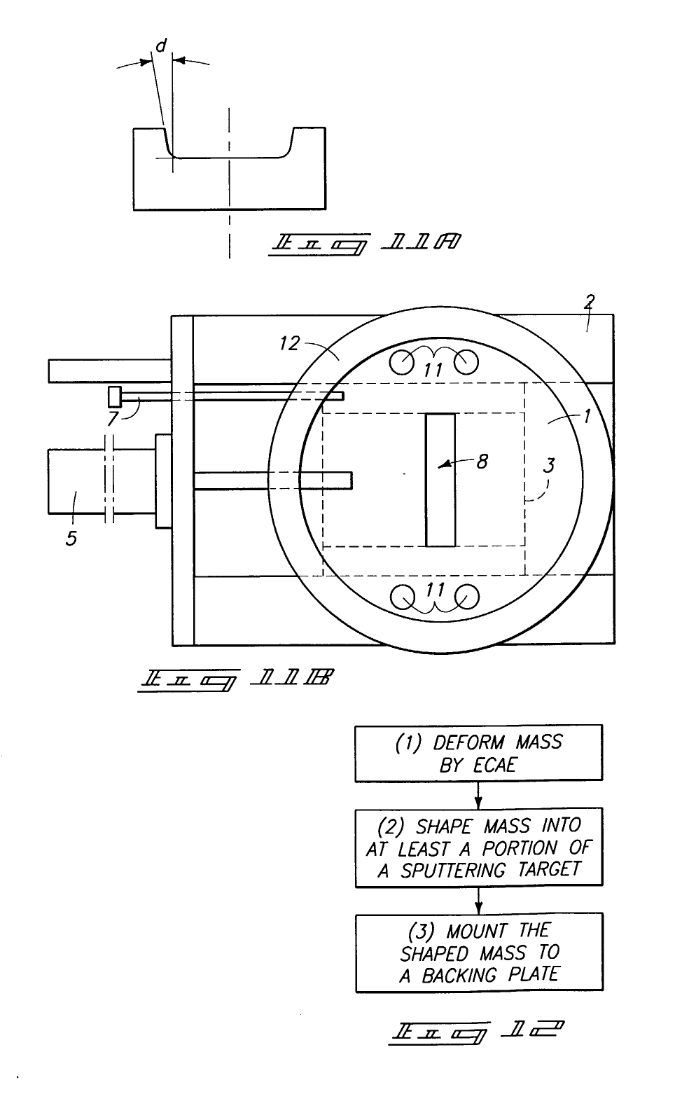

Another embodiment of the invention is an apparatus for performing the process to produce targets. The apparatus (FIGS. 11, 11A and 11B) includes die assembly 1, die base 2, slider 3, punch assembly 4,6 hydraulic cylinder 5, sensor 7, and guide pins 11. Also the die is provided with heating elements 12. Die assembly 1 has a vertical channel 8. A horizontal channel 9 is formed between die assembly 1 and slider 3. The die is fixed at table 10 of press and punch assembly 4, 6 is attached to press ram. In the original position a-a the forward end of slider 3 overlaps channel 1, punch 4 is in a top position, and a well lubricated billet is inserted into the vertical channel. During a working stroke punch 4 moves down, enters channel 8, touches the billet and extrudes it into channel 9. Slider 3 moves together with billet. At the end of stroke the punch reaches the top edge of channel 9 and then returns to the original position. Cylinder 5 moves the slider to position b-b, releases the billet, returns the slider to the position a-a and ejects the processed billet from the die. The following features are noted:

(a) During extrusion slider 3 is moved by hydraulic cylinder 5 with the same speed as extruded material inside channel 9. To control speed, the slider is provided with sensor 7. That results in full elimination of friction and material sticking to the slider, in lower press load and effective ECAE;

(b) Die assembly 1 is attached to die base 2 by guide pins 11 which provide free run 6. During extrusion the die assembly is nestled to the base plate 2 by friction acted inside channel 8. When the punch returns to the original position, no force acts on the die assembly and slider, and cylinder 3 can easily move the slider to position b-b and then eject the billet from the die.

(c) Three billet walls in the second channel are formed by the slider (FIG. 11A) that minimizes friction in the second channel.

(d) The side walls of the second channel in the slider are provided with drafts (d) from 5° to 12°. In this way the billet is kept inside the slider during extrusion but may be ejected from the slider after completing extrusion. Also, thin flash formed in clearances between the slider and die assembly may be easily trimmed.

(e) Die assembly is provided with heater 12 and springs 13. Before processing, springs 13 guarantee the clearance 6 between die assembly 1 and die base 2. During heating this clearance provides thermoisolation between die assembly and die base that results in short heating time, low heating power and high heating temperature.

The apparatus is relatively simple, reliable and may be used with ordinary presses.

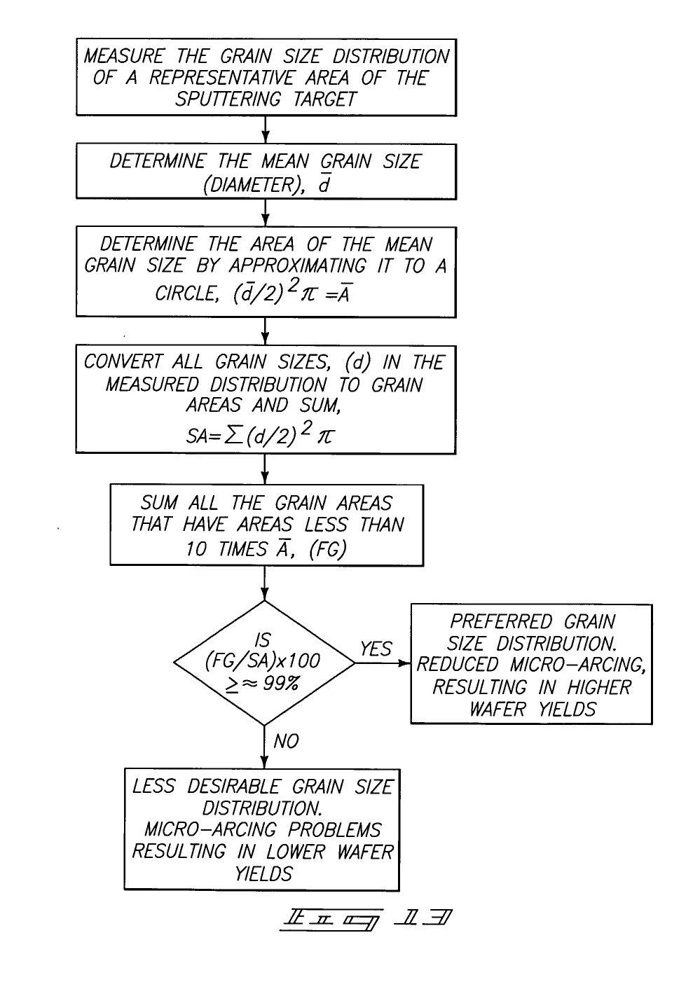

FIG. 12 shows a flow diagram of an exemplary process of the present invention. In a first step, a mass is deformed by equal channel angular extrusion (ECAE). Such deformation can be accomplished by one or more passes through an ECAE apparatus. Exemplary ECAE apparatuses are described in U.S. Pat. Nos. 5,400,633; 5,513,512; 5,600,989; and 5,590,389.

In a second step of the FIG. 12 diagram, the deformed mass is shaped into at least a portion of a sputtering target. Such shaping can comprise, for example, one or more of rolling, cross-rolling, hot forging, and cutting of the mass. The mass can be formed into a shape comprising an entirety of a sputtering target, or alternatively can be formed into a shape comprising only a portion of a sputtering target. An exemplary application wherein the mass is formed into a shape comprising only a portion of a sputtering target is an application in which the mass is utilized to form part of a so-called mosaic target. A mosaic target is a target comprising a plurality of separate target pieces which are joined to define a single large target. It can be advantageous to utilize mosaic target designs in forming large targets because it is generally easier to fabricate the small individual portions of a mosaic target than to fabricate a single large portion. If the mass is utilized in a mosaic target, it can be desired that all of the various target portions of the mosaic target be masses that have been deformed by equal channel angular extrusion prior to incorporation into the mosaic target.

In the third step of the FIG. 12 process, the shaped mass is mounted to a backing plate to incorporate the mass into a target structure. Suitable backing plates and methodologies for mounting targets to backing plates are known in the art. It is noted that the invention encompasses embodiments wherein a mass is utilized directly as a sputtering target without being first mounted to a backing plate, as well as embodiments in which the mass is mounted to a backing plate.

Processes of the present invention can be utilized to fabricate masses into targets having very fine and homogenous grain structures, with predominate sizes of the grains being less than about 50 micrometers. The present invention recognizes that improvements in grain refinement can be provided by ECAE technology relative to processing of materials. The ECAE is preferably conducted at a temperature and speed sufficient to achieve desired microstructures and provide a uniform stress-strain state throughout a processed billet.

The number of passes through an ECAE device, and the particular ECAE deformation route selected for travel through the device can be chosen to optimize target microstructures. For instance, grain refinement is a consequence of radical structural transformations occurring during intense straining by simple shear through an ECAE device. Various defects such as dislocations, shear bands, cells and subgrains are created at increased deformations during the first few ECAE passes, and divide the original grains into finer areas. Depending on the nature and composition of the materials utilized during exposure to an ECAE process, different types of grain sizes can be obtained. For instance, if ECAE processing is conducted at temperature below that of static recrystallization, grain sizes smaller than one micrometer can be produced after four or more passes through an ECAE device. Such grain sizes are smaller by a factor of at least 100 relative to the structures produced by conventional methods. For example, the static recrystallization temperature for masses of relatively pure aluminum, i.e., greater than 99.99% aluminum, is typically understood to be a temperature below about 100° C., and can be about room temperature (i.e., from about 20° C. to about 25° C.). If a temperature of static recrystallization of an aluminum-comprising mass is about room temperature, ECAE of the mass at room temperature occurring without heating of an ECAE device can provide microstructures with grain sizes of a few microns.

After ECAE, the fine areas dividing original grains within a material structure become grain-like structures by acquiring high-angle boundaries. Such process can be referred to as “mechanically-induced dynamic recrystallization,” and a principal force driving the recrystallization is plastic deformation induced solely by shear. In contrast, if ECAE is performed at a temperature higher than that of static recrystallization, both temperature effects and shear effects will produce grain growth. Accordingly, grain sizes of a few micrometers can be induced through three or more passes through an ECAE device.

At least three different aspects of ECAE contribute to the remarkable reduction of grain size and improvement of grain uniformity achieved by treating masses in accordance with the present invention. These three aspects are an amount of plastic deformation imparted by ECAE, the ECAE deformation route, and simple shear forces occurring during ECAE.

After a material has been subjected to ECAE in accordance with methods of the present invention, the material can be shaped by conventional methods of forging, cross-rolling and rolling to form the material into a suitable shape to be utilized as a target in a sputtering process. The ultrafine grain sizes created during ECAE are found to remain stable and uniform, and to show limited grain growth upon further conventional processing; even during processing comprising a high reduction in thickness of a material.

Preferably, traditional forming operations utilized for shaping a material after ECAE processing are conducted at temperatures and plastic deformations which are less than those which will occur during sputtering. For instance, if sputtering processes are anticipated to occur at about 150° C., then conventional processing of, for example, rolling, cross-rolling, or forging occurring after ECAE will preferably occur at temperatures below 150° C. By conducting such processing at temperatures below the sputtering temperature, the likelihood of the conventional processing increasing grain sizes beyond those desired in a sputtering target is reduced.

The microstructures created during ECAE are found to exhibit exceptional stability upon annealing relative to microstructures created by conventional processes. This has been verified for both submicrometer structures and micrometer structures formed within materials deformed by ECAE. For example, an ECAE processed sample showed a limited and progressive increase in grain size from approximately 12 microns to 30 microns after annealing at 150° C. for 1 hour. Such grain size did not significantly change after annealing at 150° C. for 16 hours. In contrast, samples submitted solely to rolling to an 85% reduction in thickness (a conventional process), show a dramatic grain growth up to grain sizes larger than 250 micron after annealing at only 125° C. for 1 hour. As discussed above, annealing can occur either between passes through an ECAE device, or after ECAE. It is further noted that annealing can occur between conventional processes, such as between rolling, cross-rolling and forging occurring after ECAE, or can occur subsequent to target shaping steps following ECAE. The target shaping steps preferably occur at temperatures of less than or equal to about 200° C., and more preferably occur at temperatures less than or equal to about 150° C. to keep the target shaping steps at temperatures below an ultimate sputtering temperature of a target.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

We claim:

1. A material comprising grains of sizes such that at least 99% of a measured area consists of grains that exhibit grain areas less than 10 times an area of a mean grain size of the measured area.

2. The material of claim 1 wherein at least 99% of the measured area consists of grains that exhibit grain areas less than 8 times the area of the mean grain size.

3. The material of claim 1 wherein at least 99% of the measured area consists of grains that exhibit grain areas less than 6 times the area of the mean grain size.

4. The material of claim 1 wherein at least 99% of the measured area consists of grains that exhibit grain areas less than 3 times the area of the mean grain size.

5. The material of claim 1 wherein the grains have a mean grain size of less than 3 times a minimum statically recrystallized grain size of the material.

6. The material of claim 1 wherein the grains have a mean grain size of less than a minimum statically recrystallized grain size of the material.

7. The material of claim 1 wherein the grains have a mean grain size of less than 50 microns.

8. The material of claim 1 wherein the grains have a mean grain size of about 1 to about 10 microns.

9. The material of claim 1 wherein the grains have a mean grain size of about 0.1 to about 1 microns.

10. The material of claim 1 wherein the measured area comprises at least about a statistically representative area of the material.

11. The material of claim 1 wherein the measured area comprises at least about 1000 coherent grains of the material.

12. The material of claim 1 wherein the measured area comprises an entirety of measurable surfaces of the material.

13. The material of claim 1 comprising one or more of Be, B, C, Mg, Al, Si, Ca, Sc, Ti, V, Cr, Mn, Fe, Co, Ni, Cu, Zn, Ga, Ge, Se, Sr, Y, Zr, Nb, Mo, Ru, Pd, Ag, In, Sn, Sb, Ba, La, Hf, Ta, W, Ir, Pt, Au, Bi, Ce, Nd, Sm, Eu, Gd, Tb, or Dy.

14. A sputtering target comprising the material of claim 1.

15. A thin film deposited on a substrate from the sputtering target of claim 14.

16. A material consisting of grains of sizes such that at least 99% of any measured surface area consists of grains that exhibit grain areas less than 10 times an area of a mean grain size of the measured surface area.

17. The material of claim 16 wherein the grains have a mean grain size of less than 3 times a minimum statically recrystallized grain size.

18. The material of claim 16 wherein the grains have a mean grain size of less than 50 microns.

19. The material of claim 16 wherein the measured surface area comprises at least about a statistically representative area of the material.

20. A sputtering target consisting of grains having a mean grain size of less than 3 times a minimum statically recrystallized grain size and having a distribution of grain areas such that at least 99% of a measured area consists of grains that exhibit grain areas less than 10 times an area of a mean grain size of the measured area.

21. The sputtering target of claim 20 wherein at least 99% of the measured area consists of grains that exhibit grain areas less than 8 times the area of the mean grain size.

22. The sputtering target of claim 20 wherein at least 99% of the measured area consists of grains that exhibit grain areas less than 6 times the area of the mean-grain size.

23. The sputtering target of claim 20 wherein at least 99% of the measured area consists of grains that exhibit grain areas less than 3 times the area of the mean grain size.

24. The sputtering target of claim 20 wherein the grains have a mean grain size of less than about 50 microns.

25. The sputtering target of claim 20 wherein the measured area comprises at least about a statistically representative area of the material.

26. The sputtering target of claim 20 comprising one or more of Be, B, C, Mg, Al, Si, Ca, Sc, Ti, V, Cr, Mn, Fe, Co, Ni, Cu, Zn, Ga, Ge, Se, Sr, Y, Zr, Nb, Mo, Ru, Pd, Ag, In, Sn, Sb, Ba, La, Hf, Ta, W, Ir, Pt, Au, Bi, Ce, Nd, Sm, Eu, Gd, Tb, or Dy.

27. The sputtering target of claim 20 comprising at least about 90 atomic % of Al, Ti, Cr, Co, Ni, Cu, Zr, Ru, Ag, In, Sn, Hf, Ta, Ir, Pt, or Au and from about 0.01 to about 10 atomic % of one or more of Be, B, C, Mg, Al, Si, Ca, Sc, Ti, V, Cr, Mn, Fe, Co, Ni, Cu, Zn, Ga, Ge, Se, Sr, Y, Zr, Nb, Mo, Ru, Pd, Ag, In, Sn, Sb, Ba, La, Hf, Ta, W, Ir, Pt, Au, Bi, Ce, Nd, Sm, Eu, Gd, Tb, or Dy.

28. The sputtering target of claim 20 comprising at least about 90 atomic % of Al, Ti, Cr, Co, Ni, Cu, Zr, Ru, Ag, In, Sn, Hf, Ta, Ir, Pt, or Au and from about 0.01 to about 10 atomic % of one or more of Al, Si, Ti, Cu, Ga, Nb, Mo, Pd, Ag, In, Sn, Ta, W, or Au.

29. The sputtering target of claim 20 comprising at least about 90 atomic % of Al, Ti, Cr, Co, Ni, Cu, Zr, Ru, Ag, In, Sn, Hf, Ta, Ir, Pt, or Au and from about 0.01 to about 10 atomic % of one or more of Mg, Ca, Sc, Sr, Y, Zr, Ba, La, Hf, Ce, or Nd.

30. The sputtering target of claim 20 comprising at least about 95 atomic % of Al, Ti, Cr, Co, Ni, Cu, Zr, Ru, Ag, In, Sn, Hf, Ta, Ir, Pt, or Au and from about 0.1 to about 5 atomic % of one or more of Be, B, C, Mg, Al, Si, Ca, Sc, Ti, V, Cr, Mn, Fe, Co, Ni, Cu, Zn, Ga, Ge, Se, Sr, Y, Zr, Nb, Mo, Ru, Pd, Ag, In, Sn, Sb, Ba, La, Hf, Ta, W, Ir, Pt, Au, Bi, Ce, Nd, Sm, Eu, Gd, Tb, or Dy.

31. The sputtering target of claim 20 comprising at least about 95 atomic % of Al, Ti, Cr, Co, Ni, Cu, Zr, Ru, Ag, In, Sn, Hf, Ta, Ir, Pt, or Au and from about 0.1 to about 5 atomic % of one or more of Al, Si, Ti, Cu, Ga, Nb, Mo, Pd, Ag, In, Sn, Ta, W, or Au.

32. The sputtering target of claim 20 comprising at least about 95 atomic % of Al, Ti, Cr, Co, Ni, Cu, Zr, Ru, Ag, In, Sn, Hf, Ta, Ir, Pt, or Au and from about 0.1 to about 5 atomic % of one or more of Mg, Ca, Sc, Sr, Y, Zr, Ba, La, Hf, Ce, or Nd.

33. The sputtering target of claim 20 comprising aluminum.

34. The sputtering target of claim 20 comprising titanium.

35. The sputtering target of claim 20 comprising tantalum.

36. The sputtering target of claim 20 comprising copper.

37. The sputtering target of claim 20 comprising niobium.

38. The sputtering target of claim 20 comprising nickel.

39. The sputtering target of claim 20 comprising molybdenum.

40. The sputtering target of claim 20 comprising gold.

41. The sputtering target of claim 20 comprising silver.

42. The sputtering target of claim 20 comprising platinum.

43. A thin film deposited on a substrate from the sputtering target of claim 20.

44. A micro-arc reduction method comprising sputtering a film from a sputtering target comprising grains of sizes such that at least 99% of a measured area consists of grains that exhibit grain areas less than 10 times an area of a mean grain size of the measured area.

45. The method of claim 44 wherein the sputtering target grains have a mean grain size of less than 3 times a minimum statically recrystallized grain size.

46. A sputtering target forming method, comprising:
deforming a sputtering material; and
after the deforming, shaping the sputtering material into at least a portion of a sputtering target comprising grains of sizes such that at least 99% of a measured area consists of grains that exhibit grain areas less than 10 times an area of a mean grain size of the measured area.

47. The method of claim 46 wherein at least 99% of the measured area consists of grains that exhibit grain areas less than 8 times the area of the mean grain size.

48. The method of claim 46 wherein at least 99% of the measured area consists of grains that exhibit grain areas less than 6 times the area of the mean grain size.

49. The method of claim 46 wherein at least 99% of the measured area consists of grains that exhibit grain areas less than 3 times the area of the mean grain size.

50. The method of claim 46 wherein the deforming comprises a high strain processing technique.

51. The method of claim 46 wherein the deforming comprises equal channel angular extrusion.

52. The method of claim 46 wherein, after the deforming, the sputtering target grains have a mean grain size of less than 3 times a minimum statically recrystallized grain size.

53. The method of claim 46 wherein the deforming induces an accumulated strain level corresponding to ε of at least about 4.

54. The product produced by the method of claim 46.
